(19) United States
(12) Patent Application Publication
(10) Pub. No.: US 2012/0045856 A1
(43) Pub. Date: Feb. 23, 2012

(54) METHOD OF MANUFACTURING ORGANIC EL DEVICE

(75) Inventors: Shiro SUMITA, Kanazwa-Shi (JP); Atsushi Hosoda, Kanazwa-Shi (JP); Tetsuo Ishida, Kanazwa-Shi (JP); Masuyuki Oota, Hakusan-Shi (JP)

(73) Assignee: Toshiba Mobile Display Co., Ltd., Saitama-ken (JP)

(21) Appl. No.: 13/149,821

(22) Filed: May 31, 2011

(30) Foreign Application Priority Data
Aug. 20, 2010 (JP) JP2010-184934

(51) Int. Cl. H01L 33/48

(52) U.S. Cl. 438/28; 257/E33.056

(57) ABSTRACT

According to one embodiment, a method of manufacturing an organic EL device is disclosed. The method can arrange an adhesive agent of an ultraviolet curable type between a first substrate on which a plurality of light emitting parts are formed in a predetermined direction and a second substrate arranged to face the first substrate separately so as to surround the light emitting parts. Each of the light emitting parts comprises a plurality of organic EL elements. The method can form a substrate pair by exposing the adhesive agent to ultraviolet rays to bond the first substrate and the second substrate to each other with the adhesive agent. The method can place the substrate pair on a first holding member capable of holding an entire surface of the first substrate or the second substrate. The method can place the substrate pair on a second holding member after a predetermined period of time has passed, the second holding member being capable of holding the substrate pair with at least two supporting members positioned along the first substrate or the second substrate. The method can cut the substrate pair around the adhesive agent with each of the light emitting parts as a unit.

### CROSS REFERENCE TO RELATED APPLICATIONS

This application is based upon and claims the benefit of priority from the prior Japanese Patent Application No, 2010-184934, filed on Aug. 20, 2010, the entire contents of which are incorporated herein by reference.

### FIELD

Embodiments described herein relate generally to a method of manufacturing organic EL device.

### BACKGROUND

An organic EL device is formed by bonding a first substrate on which organic EL elements are formed to a second substrate facing the first substrate with an adhesive agent. Organic EL elements are not heat-resistant, and are degraded at about 100 degrees centigrade. Therefore, instead of an adhesive agent of a heat curable type, an adhesive agent of an ultraviolet curable type that does not require heat treatment is normally used.

An adhesive agent of an ultraviolet curable type is not cured immediately after exposed to ultraviolet rays, and it takes ten hours or longer for such an adhesive agent to be completely cured. After the ultraviolet exposure, the first substrate and the second substrate are normally housed in a substrate cassette, and the both ends of the substrates are supported by two supporting members. In such a situation, the substrates are warped at the center portion due to gravity. If the warpage is large, it is difficult to secure the substrates onto a stage with a vacuum chuck. As a result, it may be difficult to cut the first substrate and the second substrate in some cases.

### BRIEF DESCRIPTION OF THE DRAWINGS

FIG. 1 is a cross-sectional view showing an example of a situation where a first substrate 1 and a second substrate 3 are bonded to each other with an adhesive agent 5.

FIG. 2 is a process chart showing steps of manufacturing the organic EL devices according to the first embodiment.

FIG. 3 is a plan view of the first substrate 1 formed in step S1 of FIG. 2.

FIG. 4 is a cross-sectional view showing a manufacturing process where the adhesive agent 5 is exposed to ultraviolet (UV) rays in step S4 of FIG. 2.

FIG. 5 is a cross-sectional view of a substrate pair 10 placed on the flat plate 15 in step S5 of FIG. 2.

FIG. 6 is a plan view of the substrate pair 10 shown in FIG. 5. As shown in FIG. 6, the upper surface of the flat plate 15 is larger than the first substrate 1 and the second substrate 3, and the flat plate 15 can hold the entire surface of the second substrate 3 of the substrate pair 10.

FIG. 7 is a cross-sectional view of substrate pairs 10 that are placed in a substrate cassette 20 in step S6 of FIG. 2.

FIG. 8A is a plan view seen from the direction A of FIG. 7.

FIG. 8B is a modified example of FIG. 8A.

FIG. 9 is a cross-sectional view of an organic EL device obtained in a case where the substrate pair 10 was held in the substrate cassette 20 for a long period of time.

FIG. 10 is a graph showing the relationship between the period of time during which a substrate pair 10 is held in the substrate cassette 20 and the warpage amount.

FIG. 11 is a graph showing the relationship between the period of time the substrate pair 10 was held on the flat plate 15 and the warpage amount.

FIG. 12 is a process chart showing steps of manufacturing the organic EL devices according to the second embodiment.

FIG. 13 is a cross-sectional view of the substrate pairs 10 held in the substrate cassette 30 in step S5′ of FIG. 12.

FIG. 14 is a plan view seen from the direction B of FIG. 13.

FIG. 15 is a cross-sectional view of substrate pairs 10 held in another substrate cassette 40.

### DETAILED DESCRIPTION

In general, according to one embodiment, a method of manufacturing an organic EL device is disclosed. The method can arrange an adhesive agent of an ultraviolet curable type between a first substrate on which a plurality of light emitting parts are formed in a predetermined direction and a second substrate arranged to face the first substrate separately so as to surround the light emitting parts. Each of the light emitting parts comprises a plurality of organic EL elements. The method can form a substrate pair by exposing the adhesive agent to ultraviolet rays to bond the first substrate and the second substrate to each other with the adhesive agent. The method can place the substrate pair on a first holding member capable of holding an entire surface of the first substrate or the second substrate. The method can place the substrate pair on a second holding member after a predetermined period of time has passed, the second holding member being capable of holding the substrate pair with at least two supporting members positioned along the first substrate or the second substrate. The method can cut the substrate pair around the adhesive agent with each of the light emitting parts as a unit.

Embodiments will now be explained with reference to the accompanying drawings.

### First Embodiment

According to a first embodiment, multiple organic EL devices are formed by bonding a first substrate and a second substrate facing each other, with a distance kept between the two substrates. The organic EL devices are then divided into individual organic EL devices.

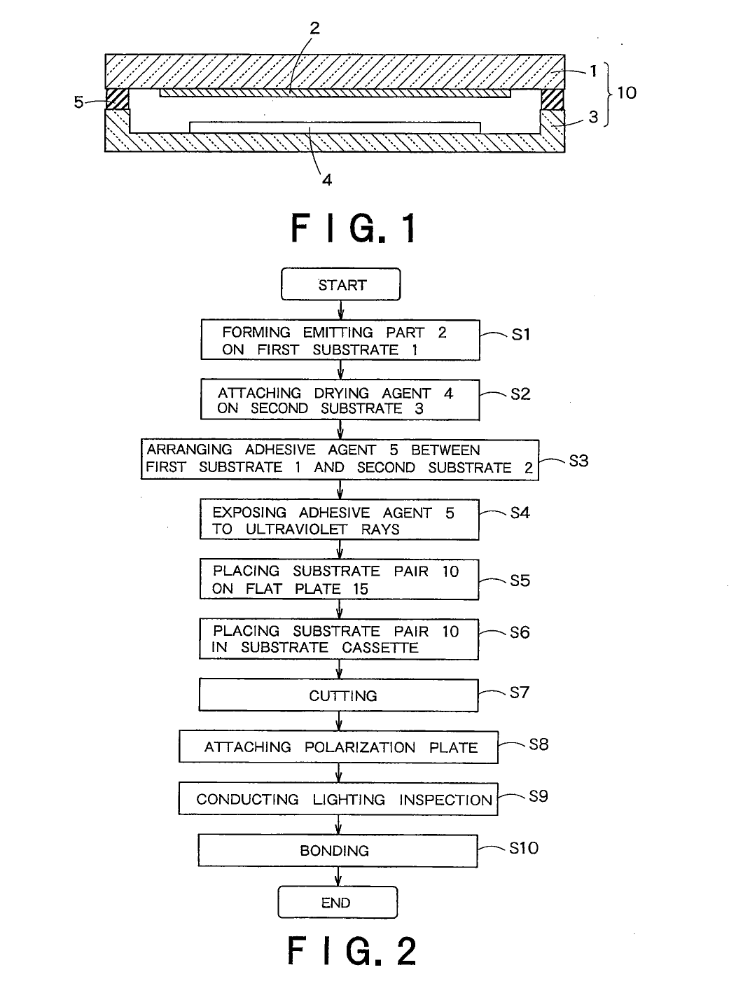

FIG. 1 is a cross-sectional view showing an example of a situation where a first substrate 1 and a second substrate 3 are bonded to each other with an adhesive agent 5. Light emitting parts 2 including organic EL elements are formed on the first substrate 1. Although not shown in the drawings, each of the organic EL elements includes an anode, a hole transport layer, a light emitting layer, an electron transport layer, an electron injection layer, and a cathode, for example. When holes injected from the anode into the light emitting layer via the hole transport layer are recombined with electrons injected from the cathode into the light emitting layer via the electron transport layer, light is emitted in a color depending on the kinds of impurities contained in the light emitting layer.

The hole transport layer is an α-NPD layer having a thickness of 200 nm, for example. The light emitting layer that also serves as the electron transport layer is an Alq3 layer having a thickness of 50 nm, for example. The electron injection layer is a LiF layer having a thickness of 1 nm, for example. The cathode is an aluminum layer having a thickness of 150 nm, for example.

A concave portion is formed on the second substrate 3, and a drying agent 4 is attached on a location facing the light emitting parts 2. The drying agent 4 may be a sheet-like member that contains calcium oxide as a main component. The drying agent 4 absorbs moisture in the organic EL devices and restrains the organic EL elements from deteriorating due to moisture.

The adhesive agent 5 is arranged between the first substrate 1 and the second substrate 3 so as to surround the light emitting parts 2. The adhesive agent 5 is cured through exposure to ultraviolet rays, and then bonds the first substrate 1 and the second substrate 3 to each other. By using the adhesive agent 5 of an ultraviolet curable type, the adhesive agent 5 can be cured without heating, the organic EL elements do not deteriorate when the adhesive agent 5 is cured.

Hereinafter, pair of the first substrate 1 and the second substrate 3 having the adhesive agent 5 therebetween will be referred to as a substrate pair 10.

FIG. 2 is a process chart showing steps of manufacturing the organic EL devices according to the first embodiment. The first embodiment shows an example where the organic EL devices to be used in printer heads for laser printers are manufactured.

Firstly, the light emitting parts 2 each including a row or rows of organic EL elements aligned in a predetermined direction are formed on the first substrate 1 made of glass or the like, with the use of an organic EL film deposition system of a resistance heating type (step S1). Meanwhile, a concave portion is formed on the second substrate 3 by chemical etching using hydrofluoric acid or the like. After water washing and ultraviolet irradiation cleaning are performed, the drying agent 4 is attached on the concave portion (step S2). It should be noted that step S2 may be carried out prior to step S1. In step S2, the concave portion may be formed by sandblasting, instead of chemical etching.

The adhesive agent 5 of an ultraviolet curable type is arranged between the first substrate 1 and the second substrate 3 so as to surround the light emitting parts 2 (step S3), and the first substrate 1 and the second substrate 3 are attached to each other. The adhesive agent 5 may be arranged under a lower pressure than atmospheric pressure, so that the air and moisture remaining in the organic EL devices are minimized. In this step, the adhesive agent 5 has not been cured yet, and the first substrate 1 and the second substrate 3 are not completely bonded to each other.

The adhesive agent 5 is then exposed to ultraviolet rays for thirty to sixty seconds, for example (step S4). To securely bond the first substrate 1 and the second substrate 3 to each other, the adhesive agent 5 may be exposed to ultraviolet rays while pressure is applied to the substrate pair 10. The adhesive agent 5 is not cured immediately after exposed to ultraviolet rays, and the adhesive agent 5 maintains fluidity immediately after the exposure to ultraviolet rays. Therefore, the substrate pair 10 is then placed on a flat plate (the first holding member) (not shown), and is held for a predetermined period of time, for example, for twenty minutes (step S5). The flat plate may be of any kind such as a shelf, as long as the flat plate can hold the entire bottom surface of the substrate pair 10.

It normally takes ten hours or longer for the adhesive agent 5 to be completely cured. The substrate pair 10 can be held on the flat plate until the adhesive agent 5 is completely cured. However, the flat plate can hold only a small number of substrate pairs 10. Therefore, in a case where organic EL devices are manufactured one after another, a large number of flat plates are required, and a wide space therefor also becomes necessary.

To counter this problem, when the adhesive agent 5 is cured to a certain degree and has the fluidity reduced on the flat plate, the substrate pair 10 is transferred from the flat plate into a substrate cassette (the second holding member) that can hold multiple substrate pairs 10 (step S6). The substrate pairs 10 are held in the substrate cassette. Since the substrate cassette can hold multiple substrate pairs 10, the space for storage can be saved.

After the substrate pairs 10 are held in the substrate cassette until the adhesive agent 5 is completely cured, for example, for twelve hours, the substrate pairs 10 are taken out of the substrate cassette. Each of the substrate pairs 10 is then fixed onto a stage with a vacuum chuck, and the substrate pairs 10 are cut around the adhesive agent 5 with a scriber device. In this manner, organic EL devices are obtained (step S7). A polarizing plate is then attached to the substrate on the light emitting side (step S8), and a lighting inspection is conducted (step S9). Further, the organic EL devices are bonded to peripheral circuits such as drive ICs (step S10). Then, the organic EL devices are incorporated into modules as printer heads. It should be noted that the lighting inspection (step S9) may be conducted prior to the polarizing plate attachment (step S8).

The manufacturing process has been described above with reference to the process chart. In the following, the manufacturing step will be described in more detail with reference to plan views and cross-sectional views.

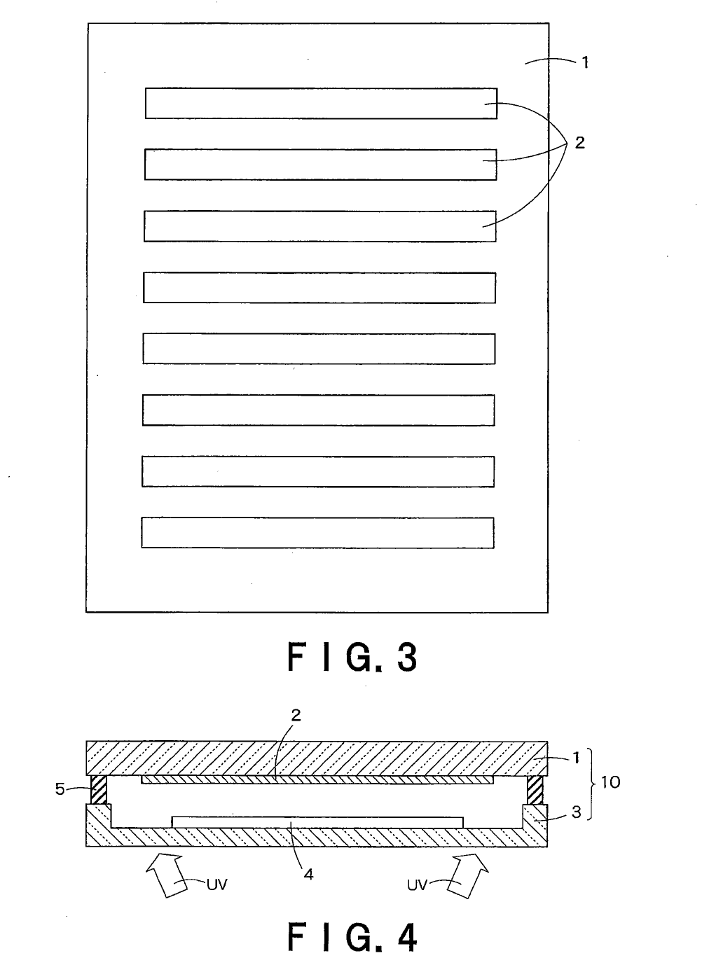

FIG. 3 is a plan view of the first substrate 1 formed in step S1 of FIG. 2. The lengths of the long side and short side of the first substrate 1 are 400 mm and 500 mm, respectively, and the thickness of the first substrate 1 is 0.7 mm, for example. As shown in FIG. 3, eight light emitting parts 2 extending in the short side direction of the first substrate 1 are arranged in the long side direction. Each of the light emitting parts 2 corresponds to an organic EL device. The lengths of the long side and short side of each of the light emitting parts 2 are 340 mm and 50 mm, respectively, for example. The length of the long side is set with printing on A4 size paper sheets in mind. Accordingly, each of the light emitting parts 2 has a horizontally long shape in each organic EL device used in printer heads.

After the light emitting parts 2 are formed, the adhesive agent 5 is arranged so as to surround the respective light emitting parts 2, and the first substrate 1 and the second substrate 3 on which the drying agent 4 is attached are attached to each other (step S3).

FIG. 4 is a cross-sectional view showing a manufacturing process where the adhesive agent 5 is exposed to ultraviolet (UV) rays in step S4 of FIG. 2. As shown in FIG. 4, in a case where ultraviolet rays are irradiated from the lower side of a substrate pair 10, that is, from the opposite surface of the second substrate 3 from the surface on which the adhesive agent 5 is arranged, the second substrate 3 is placed to face downward so that ultraviolet rays can be efficiently irradiated to the adhesive agent 5 via the portions of the second substrate 3 on which the drying agent 4 is not attached.

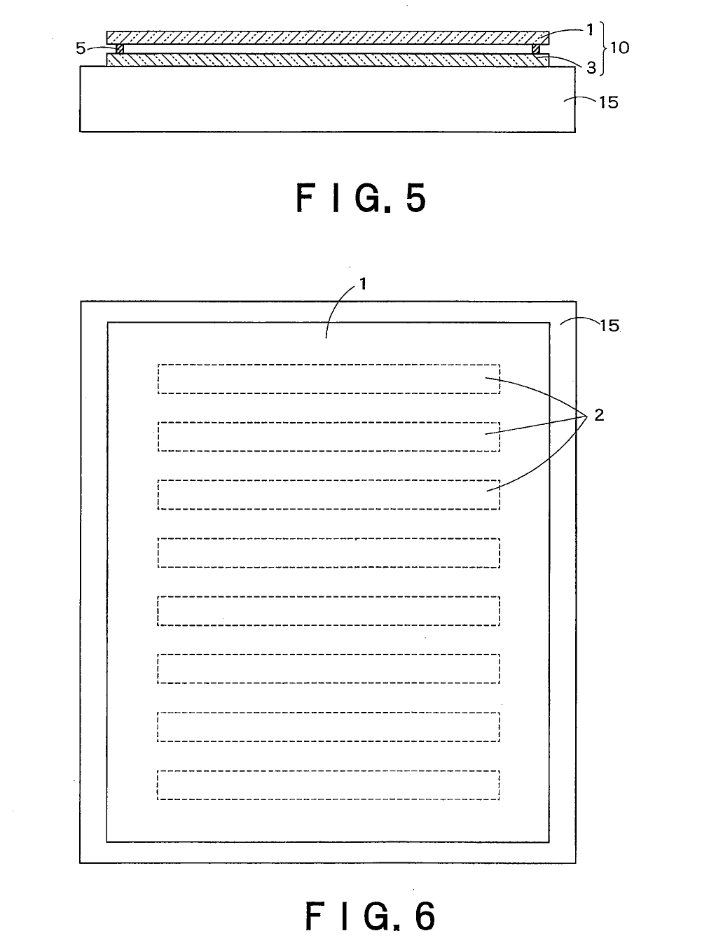

FIG. 5 is a cross-sectional view of a substrate pair 10 placed on the flat plate 15 in step S5 of FIG. 2. In FIG. 5 and the drawings following FIG. 5, the light emitting parts 2 and the drying agent 4 are not shown, unless otherwise stated. As shown in FIG. 5, when the second substrate 3 is made to face downward at the time of the ultraviolet exposure, the substrate pair 10 is placed on the flat plate 15, with the second substrate 3 facing downward. In this manner, the holding process on the flat plate 15 can be carried out after the ultraviolet exposure process, while the substrate pair 10 remains in the same orientation. Accordingly, the process efficiency can be improved.

FIG. 6 is a plan view of the substrate pair 10 shown in FIG. 5. As shown in FIG. 6, the upper surface of the flat plate 15 is larger than the first substrate 1 and the second substrate 3, and the flat plate 15 can hold the entire surface of the second substrate 3 of the substrate pair 10. Accordingly, the substrate pair 10 is not warped while being held on the flat plate 15.

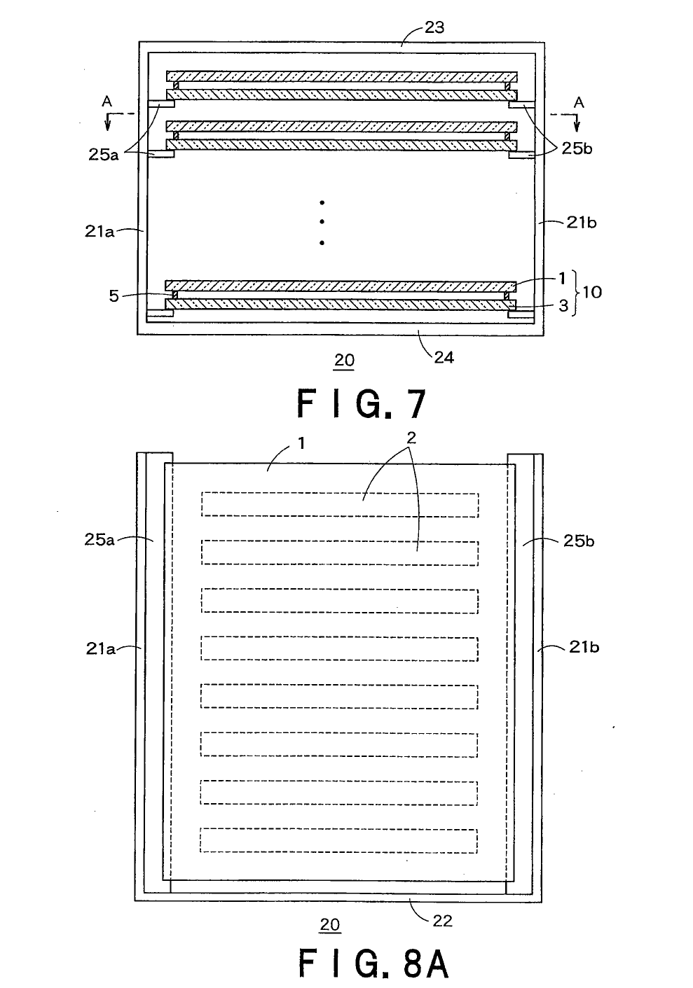

FIG. 7 is a cross-sectional view of substrate pairs 10 that are placed in a substrate cassette 20 in step S6 of FIG. 2. The substrate cassette 20 includes a pair of side plates 21a and 21b facing each other, a back plate (not shown in FIG. 7), a top plate 23, a bottom plate 24, and supporting members 25a and 25b attached to the side plates 21a and 21b. Twenty supporting members 25a and 25b are attached at regular intervals to each of the side plates 21a and 21b. Therefore, the substrate cassette 20 of FIG. 7 can horizontally hold twenty substrate pairs 10. Accordingly, the space for holding the substrate pairs 10 can be saved.

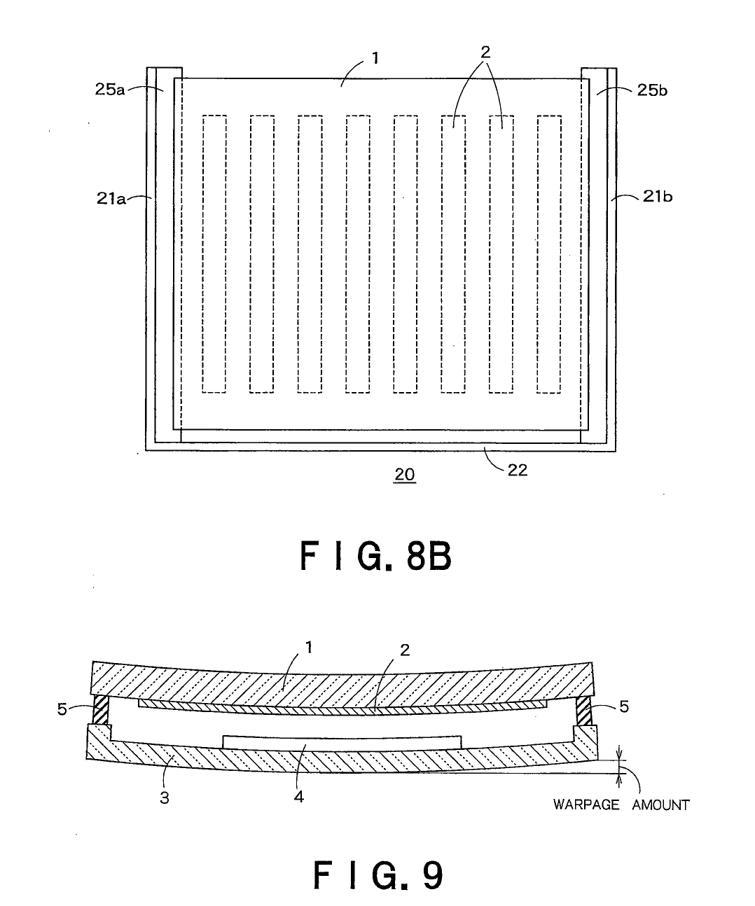

FIG. 8A is a plan view seen from the direction A of FIG. 7. The front face of the substrate cassette 20 is open, and the substrate pairs 10 gripped by a fork-like arm of a substrate transfer robot (not shown) are transferred onto the support members 25a and 25b in the substrate cassette 20 from the front side. As shown in FIG. 8, by supporting the long sides of the substrate pairs 10 on the support members 25a and 25b, warpage of the substrate pairs 10 in the substrate cassette 20 can be more effectively restrained than in a case where the short sides of the substrate pairs 10 are supported. On the other hand, as shown in FIG. 8B, when the short sides of the substrate pairs 10 are supported on the supporting members 25a and 25b, warpage of the substrate pairs 10 becomes larger, but each of the light emitting parts 2 is not warped in the long side direction. Further, warpage of the light emitting parts 2 in the short side direction becomes smaller. As a result, warpage of the organic EL devices to be obtained by cutting can be made smaller.

In the substrate cassette 20, each substrate pair 10 is supported by at least two supporting members. The two supporting members may not necessarily be attached to both of the side plates 25a and 25b, and may extend from the back plate 22, for example. Alternatively, each substrate pair 10 may be supported by three or more supporting members, or the entire surface of each substrate pair 10 may be supported by supporting members.

After the substrate pairs 10 are held in the substrate cassette 20 for a predetermined period of time, the substrate pairs 10 are cut around the adhesive agent 5 with each of the light emitting parts 2 as a unit (step S7).

If each substrate pair 10 is not held on the flat plate 15 and is held in the substrate cassette 20 immediately after the adhesive agent 5 is exposed to ultraviolet rays, the center portions of the substrate pairs 10 are warped. If the entire surface of each substrate pair 10 is held on the flat plate 15 for a predetermined period of time, on the other hand, the adhesive agent 5 is cured to a certain degree during that period. Therefore, the substrate pairs 10 are hardly warped when held in the substrate cassette 20 afterward.

To confirm this fact, an experiment was conducted in which the substrate pairs 10 were held in the substrate cassette 20 immediately after exposure to ultraviolet rays, and the substrate pairs 10 were then held on the flat plate 15 for twelve hours. The manufacturing manner in this experiment differs from those of FIG. 2. The substrate pairs 10 were held In the substrate cassette 20 for six different periods of time ranging from one minute to 120 minutes.

FIG. 9 is a cross-sectional view of an organic EL device obtained in a case where the substrate pair 10 was held in the substrate cassette 20 for a long period of time. While the substrate pair 10 was supported by two supporting members 25a and 25b in the substrate cassette 20, the center portions of the substrate pair 10 were warped downward due to gravity. Hereinafter, the difference in height between the lowest-located portion of the second substrate 3 and each end portion thereof shown in FIG. 9 will be referred to as the warpage amount.

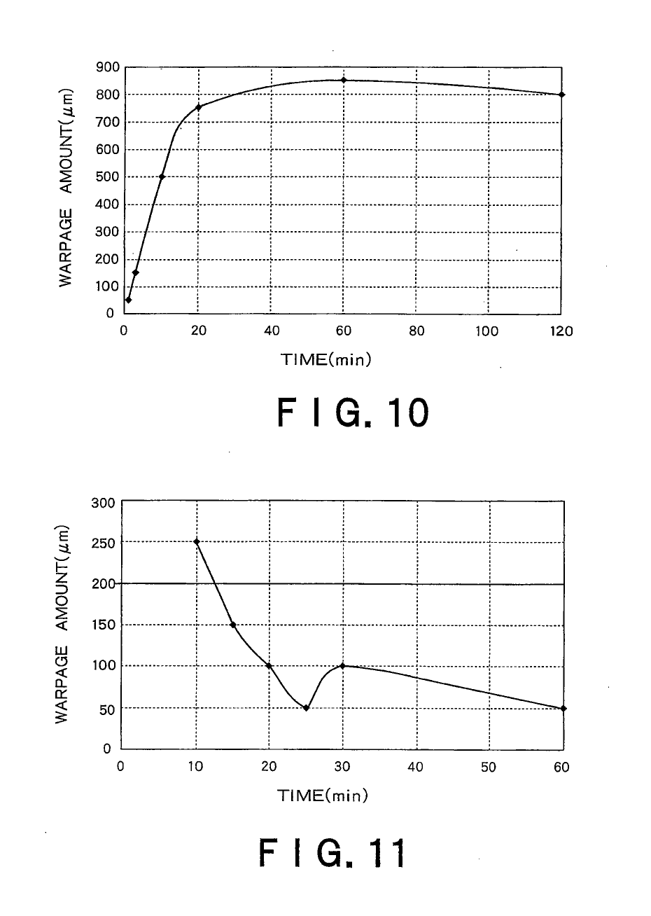

FIG. 10 is a graph showing the relationship between the period of time during which a substrate pair 10 is held in the substrate cassette 20 and the warpage amount. As can be seen from FIG. 10, in the region where the holding time in the substrate cassette 20 is about twenty minutes or shorter, as the holding time in the substrate cassette 20 is longer, the warpage amount becomes larger. This is because, the warpage of the substrate pair 10 becomes larger and larger while the substrate pair 10 is held in the substrate cassette 20, and the adhesive agent 5 flows with the warpage. In the end, the adhesive agent 5 is cured, with the substrate pair 10 in a warped state.

On the other hand, in the region where the holding time in the substrate cassette 20 is twenty minutes or longer, the warpage amount is substantially constant. This is because, after fifteen minutes have passed since the exposure to ultraviolet rays, the curing progresses, and the fluidity of the adhesive agent 5 becomes lower. Thereafter, the warpage amount does not vary greatly.

Next, the organic EL devices are manufactured through the manufacturing manner of FIG. 2 in order to confirm that warpage is restrained by holding a substrate pair 10 on the flat plate 15. The substrate pair 10 was held on the flat plate 15 (step S5) for six different periods of time ranging from ten minutes to sixty minutes. FIG. 11 is a graph showing the relationship between the period of time the substrate pair 10 was held on the flat plate 15 and the warpage amount. In the region where the holding time on the flat plate 15 is fifteen minutes or shorter, as the holding time is shorter, the warpage amount becomes larger. This is because the substrate pair 10 is placed into the substrate cassette 20 when the adhesive agent 5 is hardly cured and still has fluidity, and thus, the substrate pair 10 is warped while being held in the substrate cassette 20.

In the region where the holding time on the flat plate 15 is twenty minutes or longer, the warpage amount stays within the range of 50 μm to 100 which can be considered as substantially constant. This is because the adhesive agent 5 is already cured while being held on the flat plate 15, and the warpage amount does not vary greatly even when the substrate pair 10 is supported by two supporting members 25a and 25b in the substrate cassette 20 afterward. For example, if there are no problems in the later steps as long as the warpage amount of each substrate pair 10 is 200 μm or less, each substrate pair 10 should be held on the flat plate 15 for fifteen minutes or longer, and thereafter, may be held in the substrate cassette 20.

As described above, in the first embodiment, after the adhesive agent 5 of an ultraviolet curable type for bonding in each substrate pair 10 is exposed to ultraviolet rays, the entire surface of each substrate pair 10 is held on the flat plate 15. Accordingly, warpage of each substrate pair 10 can be restrained. Also, after the adhesive agent 5 is cured to a certain degree on the flat plate 15, each substrate pair 10 is placed into and held in the substrate cassette 20. Accordingly, organic EL devices can be efficiently manufactured in a limited space.

It should be noted that the sequence of procedures for placing the substrate pairs 10 on the flat plate 15 and in the substrate cassette 20 is not limited to the sequence shown in FIG. 2. For example, the warpage amount is small when the holding time in the substrate cassette 20 is short, as shown in FIG. 10. Therefore, after the adhesive agent 5 is exposed to ultraviolet rays, the substrate pairs 10 may be first placed into the substrate cassette 20, and, after held in the substrate cassette 20 for a predetermined period of time, may be placed on the flat plate 15. Alternatively, each substrate pair 10 may be placed first on the flat plate 15, then into the substrate cassette 20, and again back on the flat plate 15.

### Second Embodiment

In the above-described first embodiment, each substrate pair 10 is held on the flat plate 15 after ultraviolet exposure, and is then supported by two supporting members 25a and 25b in the substrate cassette 20. In a second embodiment described below, on the other hand, the flat plate 15 is not used, and the substrate pairs 10 are held with the use of a substrate cassette that does not cause warpage in the substrate pairs 10.

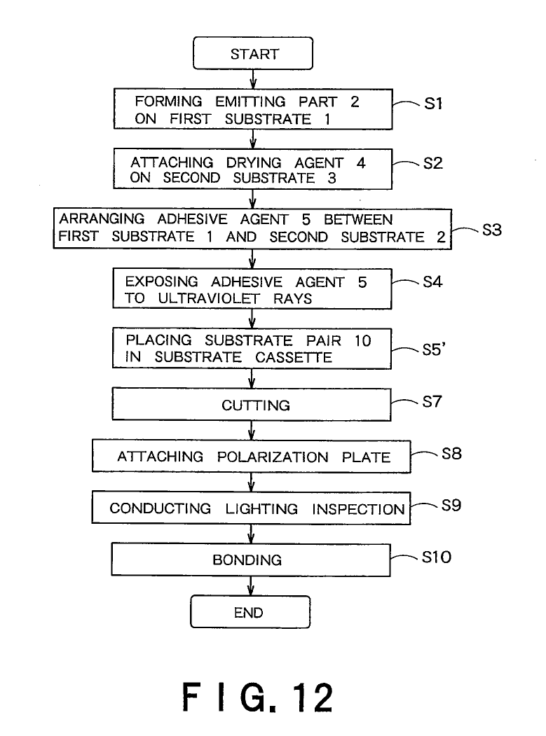

FIG. 12 is a process chart showing steps of manufacturing the organic EL devices according to the second embodiment. The second embodiment differs from the first embodiment in that each of the substrate pairs 10 is not placed on the flat plate 15 after the adhesive agent 5 is exposed to ultraviolet rays (step S4), and each of the substrate pairs 10 is placed in a substrate cassette (the third holding member) 30 in which each of the substrate pairs 10 is supported by at least three supporting members (step S5′). The other steps are similar those of the first embodiment.

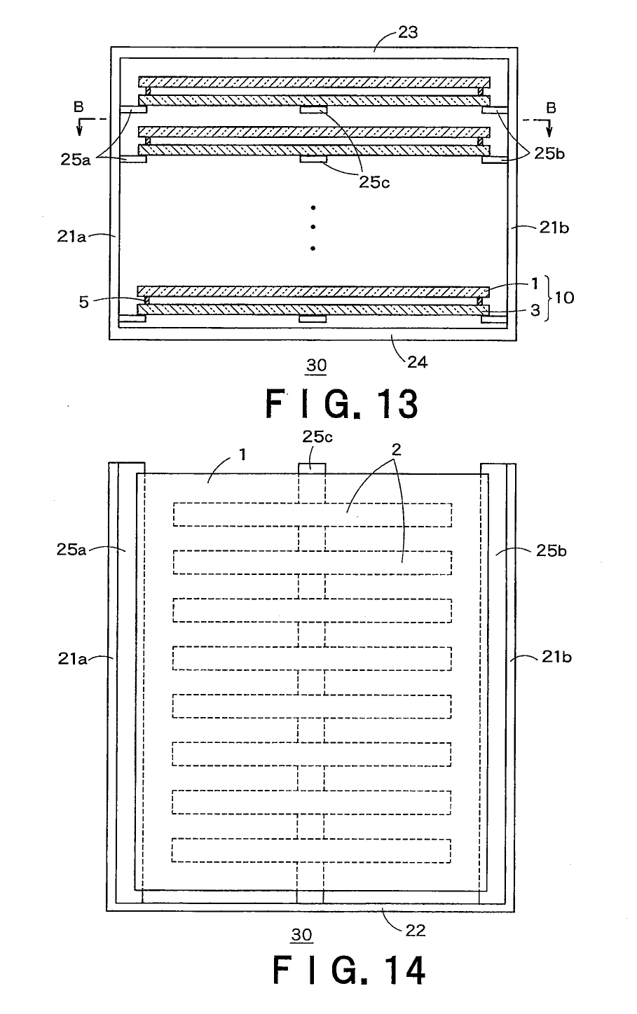

FIG. 13 is a cross-sectional view of the substrate pairs 10 held in the substrate cassette 30 in step S5′ of FIG. 12. Different from the substrate cassette 20 of FIG. 7, the substrate cassette 30 of FIG. 13 further includes supporting members 25c extending from the center portion of the back plate 22 toward the front face, and each of the supporting members 25c is positioned at the same height as each corresponding supporting member 25a and 25b. In the substrate cassette 30, each substrate pair 10 is supported by three supporting members 25a, 25b, and 25c in total. Accordingly, warpage of the substrate pairs 10 is restrained.

FIG. 14 is a plan view seen from the direction B of FIG. 13. The back plate 22 and the side plates 21a and 21b of the substrate cassette 30 may be made of plastic, for example. However, the supporting members 25c should support the substrate pairs 10 while only one end of each supporting member 25c is connected to the back plate 22 and the other end of each supporting member 25c is open. Therefore, the one end of each supporting member 25c needs to be more firmly secured to the back plate 22 with a metal or the like.

The first substrates 1 and the second substrates 3 each weigh approximately 350 g. In order to hold the first substrates 1 and the second substrates 3 without warpage, the supporting member 25c should be as strong as possible.

However, if the supporting members 25c are too heavy, the supporting members 25c come off the back plate 22. The substrate pairs 10 are not easily warped as the supporting members 25c are thicker. However, if the supporting members 25c are too thick, the arm of the substrate transfer robot collides with the supporting members 25c when the substrate pairs 10 are being transferred. Taking the above into consideration, the supporting members 25c need to be designed.

It should be noted that each of the substrate pairs 10 should be supported by at least three supporting members 25a through 25c. For example, two more supporting members may be attached to the back plate 22 of the substrate cassette 30, and each of the substrate pairs 10 may be supported by the five supporting members in total. The supporting members 25c are provided in order to restrain warpage of the substrate pairs 10, and are ideally located in the center portions between the substrate members 25a and 25b. However, even if the supporting members 25c deviate from the center portions, the effect to restrain warpage can be achieved. Also, the supporting members 25a and 25b may not necessarily be attached to both of the side plates 21a and 21b. For example, all the supporting members 25a through 25c may extend from the back plate 22. Further, the entire surface of each substrate pair 10 may be supported by supporting members.

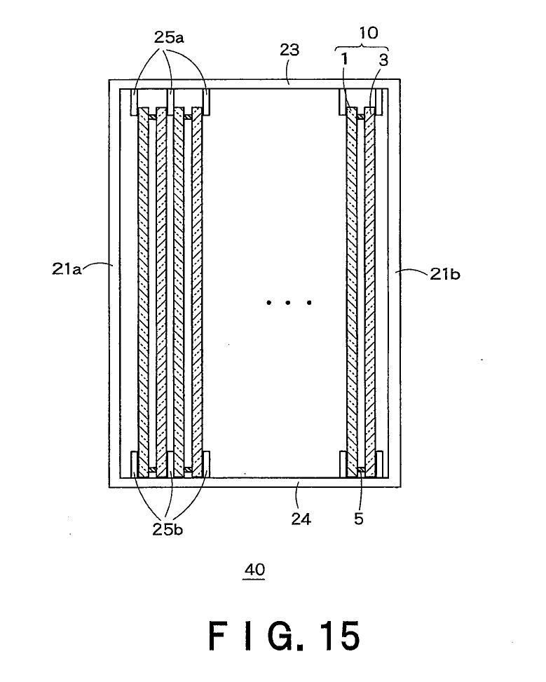

FIG. 15 is a cross-sectional view of substrate pairs 10 held in another substrate cassette 40. This substrate cassette 40 characteristically holds the substrate pairs 10 in such a direction that the substrate pairs 10 are not easily warped, and therefore, it is unnecessary to add the supporting members 25c. More specifically, in the substrate cassette 40 shown in FIG. 15, the substrate pairs 10 are held in a direction perpendicular to the substrate surfaces by supporting members 25a and 25b attached to the top plate 23 and the bottom plate 24. Warpage can also be restrained by holding the substrate pairs 10 in the perpendicular direction as shown in FIG. 15.

As described above, in the second embodiment, after the adhesive agent 5 is exposed to ultraviolet rays, the substrate pairs 10 are held with the use of the substrate cassette 30 in which each substrate pair 10 is supported by at least three supporting members 25a through 25c, or the substrate cassette 40 that holds the substrate pairs 10 in the perpendicular direction. Accordingly, warpage of the substrate pairs 10 can be restrained, and the number of procedures can be reduced compared to the first embodiment where the substrate pairs 10 are transferred from the flat plate 15 into the substrate cassette 20.

Particularly, in a case where the first substrates 1 and the second substrates 3 are large in size, the substrate pairs 10 are warped as shown in FIG. 9 if each substrate pair 10 is supported by two supporting members 25a and 25b immediately after the exposure to ultraviolet rays. It has becomes apparent through experiments that not only the above-described substrates of 400*500 mm but also substrates of 730*920 mm and substrates of 460*730 mm are warped if each substrate 10 is supported by two substrate members 25a and 25b immediately after the ultraviolet exposure. Also, as shown in FIG. 8A and others except FIG. 8B, the long sides of the substrates are supported in the substrate cassette 20. Therefore, the substrate pairs 10 are also warped if the short sides are relatively long compared with the long sides. For example, the length of each of the substrates of the above-described three types in the short side direction is at least 0.63 times as long as the length of each of the substrates in the long side direction.

Therefore, each of the above-described embodiments is useful particularly in a case where substrates having a long side length of 500 mm or longer and having a short side length that is at least 0.63 times as long as the long side length are used. When the substrate cassette 30 of FIG. 14 is used, the Intervals between the supporting members should be made shorter than 0.63 times the long side length.

The warpage shown in FIG. 9 is easily caused in a case where organic EL devices are horizontally long. Therefore, each of the above-described embodiments is particularly suitable for organic EL devices for printer heads. As described above, in printer heads that are designed with printing on A4 size paper sheets in mind, the length of the long side of each light emitting part 2 is approximately 340 mm. On the other hand, in cases where printing is performed on A3 and A5 size paper sheets, the lengths of the long sides of the light emitting parts 2 are approximately 480 mm and 240 mm, for example. In cases where printing is performed on B3, B4, and B5 size paper sheets, the lengths of the long sides of the light emitting parts 2 are 600 nm, 420 mm, and 300 mm, respectively. Meanwhile, the length of the short side of each light emitting part 2 is 50 nm, for example, regardless of paper size. Therefore, the long side of each light emitting part 2 in organic EL devices used In printer heads is 4.8 to 12 times as long as the short side of each light emitting part 2, and each of the above-described embodiments is suitable for organic EL devices including the light emitting parts 2 of such size.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. A method of manufacturing an organic EL device comprising:
arranging an adhesive agent of an ultraviolet curable type between a first substrate on which a plurality of light emitting parts are formed in a predetermined direction and a second substrate arranged to face the first substrate separately so as to surround the light emitting parts, each of the light emitting parts comprising a plurality of organic EL elements;
forming a substrate pair by exposing the adhesive agent to ultraviolet rays to bond the first substrate and the second substrate to each other with the adhesive agent;
placing the substrate pair on a first holding member capable of holding an entire surface of the first substrate or the second substrate;
placing the substrate pair on a second holding member after a predetermined period of time has passed, the second holding member being capable of holding the substrate pair with at least two supporting members positioned along the first substrate or the second substrate; and
cutting the substrate pair around the adhesive agent with each of the light emitting parts as a unit.

2. The method of claim 1, wherein the substrate pair is placed on the first holding member at least fifteen minutes.

3. The method of claim 1, wherein lengths of long sides of the first substrate and the second substrate are longer than 500 mm, respectively, and
lengths of short sides of the first substrate and the second substrate are equal to or longer than 0.63 times lengths of the lengths of the long sides.

4. The method of claim 1, wherein a length of a long side of each of the light emitting parts is 4.8 to 12 times as long as a length of a short side of each of the light emitting parts.

5. The method of claim 1, wherein the adhesive agent is exposed to the ultraviolet rays from an opposite surface of the second substrate from a surface on which the adhesive agent is arranged, and
the opposite surface of the second substrate is held on the first holding member for the predetermined period of time.

6. The method of claim 1, wherein a long side direction of the substrate pair is held on the second holding member.

7. The method of claim 1, wherein a short side direction of the substrate pair is held on the second holding member.

8. A method of manufacturing an organic EL device comprising:
arranging an adhesive agent of an ultraviolet curable type between a first substrate on which a plurality of light emitting parts are formed in a predetermined direction and a second substrate arranged to face the first substrate separately so as to surround the light emitting parts, each of the light emitting parts comprising a plurality of organic EL elements;
forming a substrate pair by exposing the adhesive agent to ultraviolet rays to bond the first substrate and the second substrate to each other with the adhesive agent;
placing the substrate pair on a second holding member capable of holding the substrate pair with at least two supporting members positioned along the first substrate or the second substrate;
placing the substrate pair on a first holding member capable of holding an entire surface of the first substrate or the second substrate after a predetermined period of time has passed; and
cutting the substrate pair around the adhesive agent with each of the light emitting parts as a unit.

9. The method of claim 8, wherein lengths of long sides of the first substrate and the second substrate are longer than 500 mm, respectively, and
lengths of short sides of the first substrate and the second substrate are equal to or longer than 0.63 times lengths of the lengths of the long sides.

10. The method of claim 8, wherein a length of a long side of each of the light emitting parts is 4.8 to 12 times as long as a length of a short side of each of the light emitting parts.

11. The method of claim 8, wherein the adhesive agent is exposed to the ultraviolet rays from an opposite surface of the second substrate from a surface on which the adhesive agent is arranged, and
the opposite surface of the second substrate is held on the first holding member for the predetermined period of time.

12. The method of claim 8, wherein a long side direction of the substrate pair is held on the second holding member.

13. The method of claim 8, wherein a short side direction of the substrate pair is held on the second holding member.

14. A method of manufacturing an organic EL device comprising:
arranging an adhesive agent of an ultraviolet curable type between a first substrate on which a plurality of light emitting parts are formed in a predetermined direction and a second substrate arranged to face the first substrate separately so as to surround the light emitting parts, each of the light emitting parts comprising a plurality of organic EL elements;
forming a substrate pair by exposing the adhesive agent to ultraviolet rays to bond the first substrate and the second substrate to each other with the adhesive agent;
placing the substrate pair on a third holding member capable of holding the substrate pair with at least three supporting members positioned along the first substrate or the second substrate; and
cutting the substrate pair around the adhesive agent with each of the light emitting parts as a unit after a predetermined period of time has passed.

15. The method of claim 14, wherein lengths of long sides of the first substrate and the second substrate are longer than 500 mm, respectively, and
lengths of short sides of the first substrate and the second substrate are equal to or longer than 0.63 times lengths of the lengths of the long sides.

16. The method of claim 14, wherein a length of a long side of each of the light emitting parts is 4.8 to 12 times as long as a length of a short side of each of the light emitting parts.

17. The method of claim 14, wherein the adhesive agent is exposed to the ultraviolet rays from an opposite surface of the second substrate from a surface on which the adhesive agent is arranged, and
the opposite surface of the second substrate is held on the first holding member for the predetermined period of time.

18. The method of claim 14, wherein a long side direction of the substrate pair is held on the second holding member.

19. The method of claim 14, wherein a short side direction of the substrate pair is held on the second holding member.

20. A method of manufacturing an organic EL device comprising:
arranging an adhesive agent of an ultraviolet curable type between a first substrate on which a plurality of light emitting parts are formed in a predetermined direction and a second substrate arranged to face the first substrate separately so as to surround the light emitting parts, each of the light emitting parts comprising a plurality of organic EL elements;
forming a substrate pair by exposing the adhesive agent to ultraviolet rays to bond the first substrate and the second substrate to each other with the adhesive agent;
placing the substrate pair substantially perpendicular to a substrate surface; and
cutting the substrate pair around the adhesive agent with each of the light emitting parts as a unit after a predetermined period of time has passed.

21. The method of claim 20, wherein lengths of long sides of the first substrate and the second substrate are longer than 500 mm, respectively, and
lengths of short sides of the first substrate and the second substrate are equal to or longer than 0.63 times lengths of the lengths of the long sides.

22. The method of claim 20, wherein a length of a long side of each of the light emitting parts is 4.8 to 12 times as long as a length of a short side of each of the light emitting parts.

23. The method of claim 20, wherein the adhesive agent is exposed to the ultraviolet rays from an opposite surface of the second substrate from a surface on which the adhesive agent is arranged, and
the opposite surface of the second substrate is held on the first holding member for the predetermined period of time.
